(19) United States
(12) Patent Application Publication
(10) Pub. No.: US 2009/0180313 A1
(43) Pub. Date: Jul. 16, 2009

(54) Chalcogenide anti-fuse

(76) Inventors: Wim Deweerd, San Jose, CA (US); Derchang Kau, Cupertino, CA (US); Robert J. Gleixner, San Jose, CA (US)

Correspondence Address: TROP, PRUNER & HU, P.C., 1616 S. VOSS RD., SUITE 750, HOUSTON, TX, 77057-2631, US

(21) Appl. No.: 12/008,970

(22) Filed: Jan. 15, 2008

(51) Int. Cl. H01L 45/00; G11C 11/00

(52) U.S. Cl. 365/163; 438/600; 438/95; 257/2; 257/E45.002

(57) ABSTRACT

An ovonic threshold switch may be used to form an anti-fuse. As manufactured, the fuse may be in its amorphous state, as is conventional for ovonic threshold switches. However, when exposed to a sufficient voltage under appropriate circumstances, the anti-fuse may fuse in a more conductive state. As fused, the cell may exhibit both crystalline characteristics in the chalcogenide material and mixing of electrode material into the chalcogenide, rendering the anti-fuse in a generally irreversible conductive or crystalline state.

### BACKGROUND

This relates generally to anti-fuses which are one time programmable memory elements generally fused in the on or conductive state.

An anti-fuse or a fuse may be used for a variety of functions in connection with semiconductor devices. One Time Programmable (OTP) memory elements may be used to store manufacturer controlled information after wafer level sort and/or after die packaging. It is desirable that this information withstand the high temperatures that are involved with packaging and mounting the product and are reliable in both programming and subsequent use. In other words, if the information is lost when the integrated circuit is packaged, the information is of no value.

Traditional fuses may be operated by exposing material to heat applied by laser light, thereby permanently opening the fuse device into a high-resistive state.

### BRIEF DESCRIPTION OF THE DRAWINGS

FIG. 1 is a schematic depiction of one embodiment of the present invention in its unprogrammed state;

FIG. 2 is a schematic depiction of the embodiment of FIG. 1 in its programmed or anti-fused state;

FIG. 3 is a graph of current versus voltage for the unprogrammed (A) and programmed (B) for one exemplary embodiment; and

FIG. 4 is a system depiction for one embodiment of the present invention.

### DETAILED DESCRIPTION

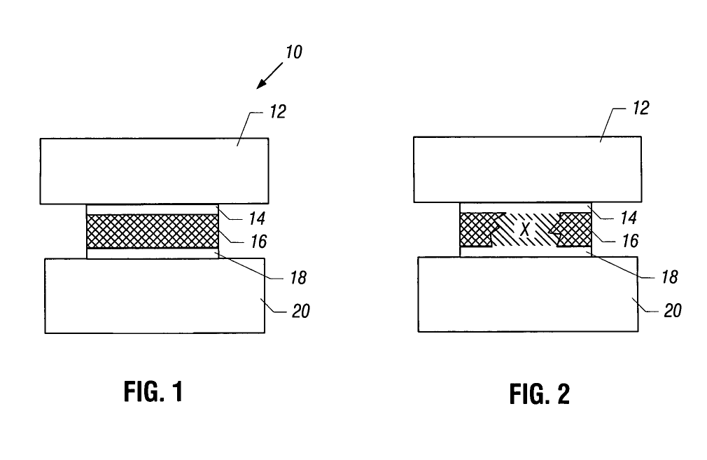

Referring to FIG. 1, an anti-fuse 10 may be a single, One Time Programmable element or may be part of an array of one time programmable elements arranged, for example, in rows and columns. Each one time programmable element or anti-fuse 10 may include an upper metal line 12, such as a column line, coupled to a top electrode 14.

The top electrode 14, ovonic threshold switch material 16, and bottom electrode 18 make up a dot in one embodiment. A dot is a stack of layers of material that has been etched to common peripheral edge dimensions. The dot may be positioned under the metal line 12, which may be common to a plurality of dots making up an array of one time programmable anti-fuses in some embodiments.

Below the dot may be a layer 20 that includes an electrode, a memory element and electrode, or a heater. The layer 20 may be contacted below by a potential source such as row line (not shown). When current passes from between the row line and the metal line 12, the chalcogenide memory material in an ovonic unified memory (OUM) may be heated, for example, by self-heating or by heating from an external heater. The electric current passing through the Ovonic Threshold Switch may be used to irreversibly change the state of the ovonic threshold switch material 16 to an at least partially crystalline and/or mixed phase, in some embodiments.

An ovonic threshold switch (OTS) is a chalcogenide switch generally used as a selection device in an ovonic unified memory. The ovonic threshold switch is only used in its amorphous state and does not change phase in normal operation.

Thus, in the case of a one time programmable element in the form of an anti-fuse, the anti-fuse ovonic threshold switch material 16 may be programmed by passing current through the switch. The term “program” is used in the context of an anti-fuse to infer that the anti-fuse is shorted so that it is less resistive.

In the case of an ovonic threshold switch, shorting basically means that the device irreversibly assumes a lower resistance, (partially) crystallized state. Without being bound by theory, the transition may be marked by intermixing of the OTS material with the electrode material, atomic migration, or electrochemical bonding, in some embodiments. The material may or may not be completely crystalline, but, generally, exhibits resistances in the kiloOhm range in some embodiments.

A variety of different materials may be utilized to form the ovonic threshold switch material. As one example, a chalcogenide glass, including arsenic, germanium, and tellurium, may be utilized, together with bottom and top electrodes 14 and 18, containing titanium.

The anti-fuse 10 is programmed or fused by applying a voltage larger than the threshold voltage of the ovonic threshold switch material 16. The threshold voltage may be determined by the thickness of the material and its composition. Sufficient current flows across the ovonic threshold switch material 16 to short it permanently and irreversibly. The lower resistance state is a consequence of crystallization of the ovonic threshold switch material 16 and phase mixing of the ovonic threshold switch with the electrodes 14 and 16, as shown in FIG. 2 at X. The change in resistance is relatively large, enabling fast and low power reading in a high read operating window. Reading may be done below the ovonic threshold switch threshold level in order not to disturb the non-programmed anti-fuse.

In an embodiment in which the ovonic threshold switch is used with an ovonic memory element or OUM, the ovonic memory element may be in its low resistance or crystalline state after packaging, due to the high temperatures involved in packaging. A non-fused cell with a set ovonic memory element, but a highly resistive ovonic threshold switch state enabling sub-threshold reading of the cell, may have a net high resistance in the megaOhm range in one embodiment.

In some embodiments, multiple layers of dots may be stacked one on top of the other, forming a cross-point memory configuration.

In order to obtain the fusing described herein, a relatively high voltage may be applied with a rising edge to a holding time, followed by a falling edge. For example, in one embodiment, an 8 volt pulse with 5 microsecond rise, 5 microsecond fall, and 0.5 microsecond holding time may be used to short switches formed of arsenic, germanium, and tellurium into the low-resistive state. To break the fuse, currents in the low milliamp range may be used and/or voltages around 4 to 8 volts, depending on the threshold voltage of the ovonic threshold switch embodiment.

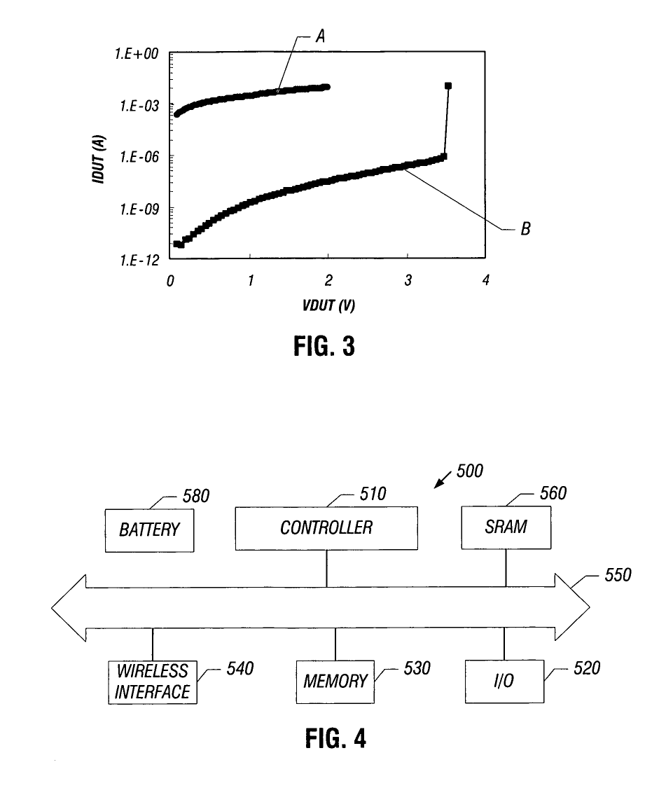

Thus, in accordance with one embodiment shown in FIG. 3, the unprogrammed or non-fused state B of the ovonic threshold switch IV curve shows a high resistance condition. After programming, with lower resistance, the fuse irreversibly assumes the more crystalline lower resistance state A. In the embodiment shown in FIG. 3, a 0.4 micrometer dot size was utilized without a memory element+heater configuration.

The anti-fuse may be programmed and will withstand baking for an extended period of time. On the other hand, temperatures of up to 200° C. do not cause the non-fused bit to fuse. In other words, the unprogrammed ovonic threshold switch does not become programmed based on such a temperature exposure, nor will a programmed cell become highly resistive again. Temperatures of up 200° C. may be encountered in packaging. Thus, if temperatures are maintained at a level that does not cause fusing of the bit, which can be done with conventional packaging processing, the bit is unfused as packaged and thereafter can be programmed either by the manufacturer or the user in the field.

Referring to FIG. 2, in the fused region X, there may be crystalline chalcogenide material, as well as mixing of the bottom electrode 18 and top electrode 14.

Generally, a filament or fused region may be formed at some portion along the width of the ovonic threshold switch 16. Outside the filament, the material may remain, in some embodiments, in the amorphous state, as indicated in FIG. 2.

Forming a low resistive state or short from the high resistance OTS material may involve forming only one conductive path in some embodiments. This use of only one conductive path can be advantageous in terms of writing to a fuse reliably, as well as reading from it, in some embodiments.

Turning to FIG. 4, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a chalcogenide anti-fuse.

2. The method of claim 1 including forming the chalcogenide anti-fuse to be irreversibly programmable to an at least partially crystalline state.

3. The method of claim 2 including forming said chalcogenide anti-fuse from an ovonic threshold switch.

4. The method of claim 1 including providing a metallic layer in contact with said anti-fuse to be programmed.

5. The method of claim 1 including forming said anti-fuse of a chalcogenide including arsenic, germanium, and tellurium.

6. The method of claim 1 including forming said anti-fuse in association with a chalcogenide memory element.

7. The method of claim 1 including causing said programmed anti-fuse to have a resistance about 1000 times less than said unprogrammed chalcogenide anti-fuse.

8. The method of claim 1 including causing the chalcogenide anti-fuse when programmed to mix electrode material into the chalcogenide material and crystallize.

9. The method of claim 1 including forming a field programmable anti-fuse.

10. The method of claim 1 including forming said anti-fuse of an amorphous chalcogenide that is programmable by transitioning to a crystalline phase.

11. An apparatus comprising:
a first electrode;
a second electrode; and
a chalcogenide anti-fuse between said first and second electrodes.

12. The apparatus of claim 11 wherein said chalcogenide anti-fuse being irreversibly programmable to at least a partially crystalline state.

13. The apparatus of claim 12 wherein said chalcogenide anti-fuse is an ovonic threshold switch.

14. The apparatus of claim 11 including a metallic layer in contact with said heater.

15. The apparatus of claim 11 wherein said anti-fuse includes arsenic, germanium, and tellurium.

16. The apparatus of claim 11 including an ovonic unified memory element coupled to said anti-fuse.

17. The apparatus of claim 11 wherein the programmed anti-fuse has a resistance of about 1000 times less than the unprogrammed anti-fuse.

18. The apparatus of claim 11 wherein when said anti-fuse is programmed, the anti-fuse includes material from at least one of said first and second electrodes.

19. The apparatus of claim 11 wherein said anti-fuse is field programmable.

20. The apparatus of claim 11 wherein said anti-fuse includes amorphous chalcogenide.

21. The apparatus of claim 20 wherein said amorphous chalcogenide is programmable via the formation of a crystalline filament.

22. A system comprising:
a processor;
a static random access memory coupled to said processor; and
a chalcogenide anti-fuse coupled to said processor, said anti-fuse including a first electrode, a second electrode, and a chalcogenide anti-fuse between said first and second electrodes.

23. The system of claim 22 wherein said chalcogenide anti-fuse being irreversibly programmable to at least a partially crystalline state.

24. The system of claim 23 wherein said chalcogenide anti-fuse is an ovonic threshold switch.

25. The system of claim 22 including a heater to program said anti-fuse.

26. The system of claim 22 including an ovonic unified memory element coupled to said anti-fuse.
